(19) United States
(12) Patent Application Publication
(10) Pub. No.: US 2011/0114149 A1
(43) Pub. Date: May 19, 2011

(54) JUNCTION BOX AND PHOTOVOLTAIC MODULE HAVING JUNCTION BOX

(75) Inventor: Szu-Han LI, Zhongli City (TW)

(73) Assignee: Du Pont Apollo Limited, Hong Kong (HK)

(21) Appl. No.: 12/944,725

(22) Filed: Nov. 12, 2010

Related U.S. Application Data
(60) Provisional application No. 61/261,166, filed on Nov. 13, 2009.

(51) Int. Cl. H01L 31/042; H02G 3/14

(52) U.S. Cl. 136/244; 220/3.8

(57) ABSTRACT

A junction box and a photovoltaic module having a junction box are described. The junction box includes an upper cover having an upper extending wing, a lower cover having a lower extending wing, and a sealant applying thereon to glue the junction box to a solar panel. The upper cover and the lower cover form a U-shaped clamp to clamp the solar panel. The junction box can be firmly fixed on the solar panel with a fixing member or protrusions coupling to trenches formed on the solar panel.

### RELATED APPLICATIONS

This application claims priority to US Provisional Application Ser. No. 61/261,166, filed Nov. 13, 2009, which is herein incorporated by reference.

### FIELD OF THE INVENTION

The present invention generally relates to a junction box. More particularly, this invention relates to a junction box of a photovoltaic module.

### BACKGROUND OF THE INVENTION

The increasing scarcity, and the realization of the ecological and safety problems associated with non-renewable energy resources such as coal, petroleum and uranium, have made it essential that increased use be made of alternate non-depletable energy resources such as solar energy. Solar energy use has been limited in the past to special application due in part to the high cost of manufacturing devices capable of producing significant amounts of photovoltaic energy. The improvement in manufacture technology for fabricating the solar panel in mass production has greatly promoted the use of solar energy.

Significant environmental benefits are also realized from solar energy production, for example, reduction in air pollution from burning fossil fuels, reduction in water and land use from power generation plants, and reduction in the storage of waste byproducts. Solar energy produces no noise, and has few moving components. Because of their reliability, solar panels also reduce the cost of residential and commercial power to consumers.

A photovoltaic (PV) cell can convert light energy into electric energy. The solar panel contains a plurality of PV cells. Each solar panel has a positive output and a negative output, and the positive output and the negative output of the solar panel are electrically connected to a common positive output wire and a common negative output wire, respectively. The terminals of the positive and negative outputs typically pass through the back sheet of the solar panel. After the positive and negative outputs are soldered onto the outside of the solar panel, it is necessary to connect the positive and negative outputs with positive output cable and negative output cable, respectively, to convey the electric current from the solar panel, such that the electric current can be used for its intended purpose.

To protect these soldered connections from damage or short circuit, a protective structure, commonly called as a “junction box”, is positioned and secured over these soldered connections and the junction box is filled with a protective sealant, such as epoxy, to cover and protect these soldered connections. Also, it is needless to say that the junction box has to be firmly attached onto the back sheet of the solar panel. However, the conventional junction box has poor fixing strength due to the lack of gluing area between the junction box and the back sheet. Accordingly, it can be seen that a junction box which can be firmly secured onto the back sheet of the solar panel would be highly beneficial in the manufacture and marketing of solar panel.

### SUMMARY OF THE INVENTION

One objective of the present invention is to provide a junction box with extending wings to effectively protect the electronic connections for a photovoltaic module and firmly fix the junction box on the photovoltaic module.

To achieve these and other advantages and in accordance with the objective of the present invention, as the embodiment broadly describes herein, the present invention provides a junction box including an upper cover having an upper base portion and an upper extending wing, and a lower cover having a lower base portion and a lower extending wing, and a fastener disposed at a contact area between the upper cover and the solar panel, and the lower cover and the solar panel to fix the junction box to the solar panel.

The upper cover and the lower cover form a U-shaped clamp to clamp the solar panel when the upper base portion is coupled to the lower base portion. The upper cover further includes an upper cavity and the lower cover further includes a lower cavity to form a protective room to protect electronic connections for the solar panel. The fastener can be a sealant applied to the contact area to glue the junction box onto the solar panel. In addition, the sealant can further be filled into the protective room formed by the upper cavity and the lower cavity to effectively protect the electronic connections therein. The sealant is epoxy, for example.

The fastener can be a protrusion protruded from the upper cover and the lower cover, and the solar panel further comprises a trench to be engaged with the protrusion.

Moreover, the fastener can be a fixing member to couple the upper extending wing, the solar panel and the lower extending wing together.

Another aspect of the present invention is to provide a photovoltaic module including a solar panel having two conductive wires protruding from the solar panel, two terminals respectively connecting to the conductive wires, two cables respectively connecting to the terminals, and the foregoing junction box mounting on an edge of the solar panel

The photovoltaic module further includes a bypass diode connecting to the two terminals. The conductive wires are flat conductive wire, for example. In an embodiment, the flat conductive wire is made of a copper material and coated with a hot dipped Tin coating.

Accordingly, the junction box with extending wings according to the present invention can effectively protect the electronic connections for the photovoltaic module and the junction box can be firmly fixed on the solar panel with enlarged contact area therebetween and sealant, e.g. epoxy. In addition, the junction box can be fixed on the edge of the solar panel with an additional fixing member or protrusions formed on the extending wings.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 illustrates an embodiment of a photovoltaic module with a junction box according to the present invention;

FIG. 2 illustrates the detailed internal configuration of a junction box fixed on a solar panel; and

FIGS. 3A to 3C illustrate a plurality of embodiments to show the junction box fixed on the solar panel.

### DETAILED DESCRIPTION OF THE PREFERRED EMBODIMENT

The following description is of the best presently contemplated mode of carrying out the present invention. This description is not to be taken in a limiting sense but is made merely for the purpose of describing the general principles of the invention. The scope of the invention should be determined by referencing the appended claims.

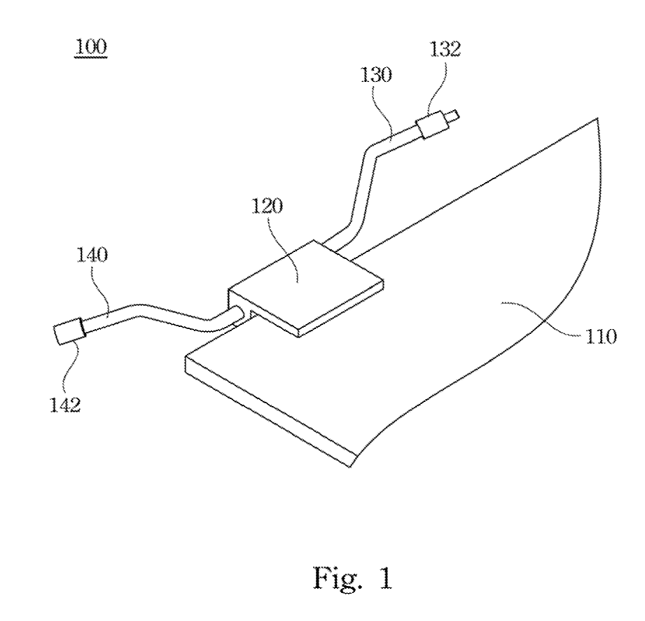

Refer to FIG. 1. FIG. 1 illustrates a preferred embodiment of a photovoltaic module with a junction box according to the present invention. The photovoltaic module 100 has a solar panel 110 and a junction box 120 side mounted on an edge of the solar panel 110. The photovoltaic module 100 further includes a cable 130 and a cable 140 electrically connecting to the conductive wires in the junction box 120 to output the electric current from the photovoltaic module 100 to an electronic device (not shown) or connect to another photovoltaic module 100 in series or parallel. The cable 130 can further install a connector 132 thereon and the cable 140 can further install a connector 142 thereon to conveniently connect to the photovoltaic module 100 to another photovoltaic module 100 in series or an electronic device.

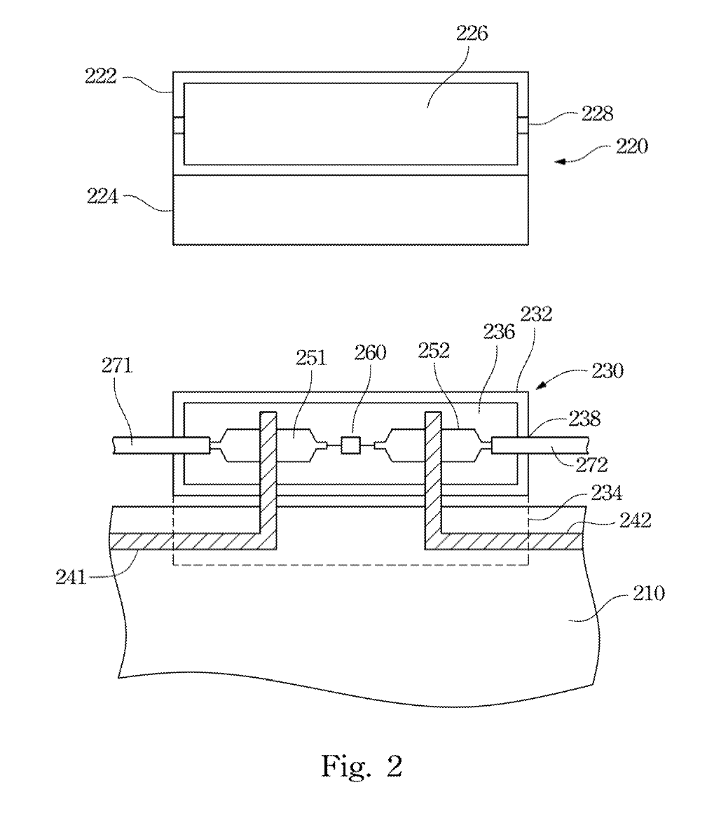

Refer to FIG. 2. FIG. 2 illustrates the detailed internal configuration of the junction box fixed on the solar panel. The upper cover 220 includes a base portion 222, and an extending wing 224 extending from the base portion 222.

In addition, a cavity 226 is formed in the base portion 222 of the upper cover 220, and a cable passage 228 is formed on the sidewall of the base portion 222 to allow a cable passing therethrough. Furthermore, the lower cover 230 includes a base portion 232, and an extending wing 234 extending from the base portion 232. In addition, a cavity 236 is formed in the base portion 232 of the lower cover 230, and a cable passage 238 is formed on the sidewall of the base portion 232 to allow the cable passing therethrough.

The cavity 236 in the lower cover 230 is to accommodate and protect electronic connections, e.g. the soldered connections of the electronic components accommodated in the junction box, of the photovoltaic module. A conductive wire 241 and a conductive wire 242 protruding form the solar panel 210 are respectively connected to positive outputs and negative outputs of photovoltaic cells in the photovoltaic module. A terminal 251 and a terminal 252 are further connected to the conductive wire 241 and the conductive wire 242 respectively, and a bypass diode 260 is connected between the terminal 251 and the terminal 252 to protect the photovoltaic module. In addition, a cable 271 and a cable 272 are respectively connected to the terminal 251 and the terminal 252 to output the electric current to the outside of the photovoltaic module.

The conductive wire 241/242 can be a flat conductive wire, e.g. an oblong cross-section conductive wire, to form the bus bars and cell interconnects in the photovoltaic module. The conductive wire 241/242 can be made of the copper material and coated with a solder coating such as a hot dipped Tin coating. In addition, the terminal 251 and the terminal 252 are connected to the conductive wire 241 and the conductive wire 242 respectively by clamping or soldering. The terminal 251 and the terminal 252 can also be made of the copper material and coated with a solder coating such as a hot dipped Tin coating. The terminal 251 and the terminal 252 can be flat terminals with an oblong cross-section.

When the upper cover 220 is coupled to the lower cover 230, the cavity 226 and the cavity 236 are combined together to form a protective room for accommodating and protecting the electronic connections. The protective room formed by the cavity 226 and the cavity 236 can be further filled with a protective sealant, e.g. epoxy, to further protect the electronic connections therein. In addition, the base portion 222, the extending wing 224, the base portion 232, and the extending wing 234 form a U-shaped clamp to clamp an edge of the solar panel 210. The extending wing 224 and the extending wing 234 can effectively extend the contact area between the junction box and the solar panel 210 to further improve the clamping force therebetween.

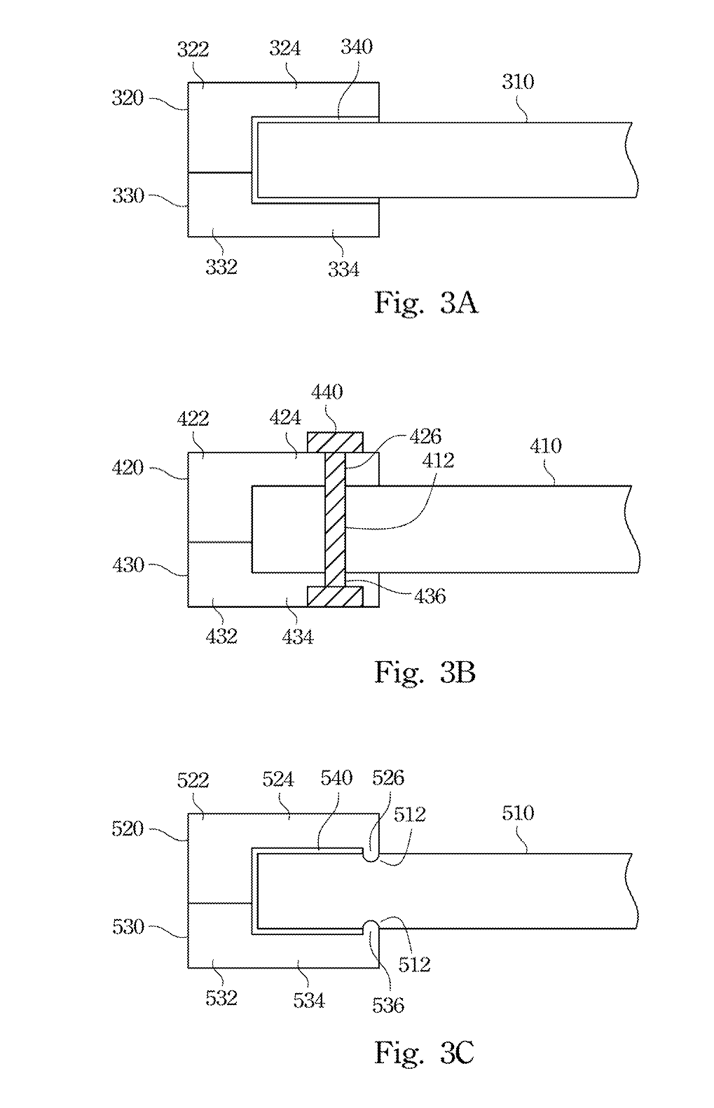

Furthermore, FIGS. 3A to 3C illustrate a plurality of embodiments to show the junction box fixed on the solar panel. In the FIG. 3A, the solar panel 310 is clamped by the upper cover 320 and the lower cover 330. The solar panel 310 can be further glued to the base portion 322, the extending wing 324, the base portion 332 and the extending wing 334 by sealant 340, e.g. epoxy. The extending wing 324 and the extending wing 334 can effectively extend the contact area between the extending wing 324, the extending wing 334 and the solar panel 310, and therefore the fixing strength therebetween can be effectively increased.

In FIG. 3B, the solar panel 410 is clamped by the upper cover 420 and the lower cover 430 of the junction box. A fixing member 440, e.g. a bolt and a nut, further passes through the extending wing 424, the solar panel 410 and the extending wing 434 to increase the clamping force between the junction box and the solar panel 410. Therefore, an opening 426 can be formed in the extending wing 424, an opening 436 can be formed in the extending wing 434, and an opening 412 can be formed in the solar panel 410 to allow the fixing member 440 passing through and fixing them together. In addition, a sealant can be also applied to the junction box and the solar panel 410 to further improve the fixing strength therebetween as mentioned in FIG. 3A.

In FIG. 3C, the solar panel 510 is clamped by the upper cover 520 and the lower cover 530 of the junction box. The end portion of the upper cover 520 can further include a protrusion 526 to couple to a trench 512 formed on the substrate of the solar panel 510. Alternatively, the end portion of the lower cover 530 can further include a protrusion 536 to couple to a trench 512 formed on the substrate of the solar panel 510. Therefore, the junction box can be firmly mounted on the edge of the solar panel 510. The junction box can also include two protrusions 526 and 536 respectively formed on the end portions of the upper cover 520 and the lower cover 530 to firmly mount the junction box on the edge of the solar panel 510. The upper cover 520 and the lower cover 530 can further be glued to the solar panel 510 with the sealant 540. In addition, the fixing member 440 can also be used in the solar panel 510 and the junction box while the corresponding openings are formed on the solar panel 510, the upper cover 520, and the lower cover 530.

Accordingly, the junction box according to the present invention adopts the extending wings to clamp the solar panel, and the contact area between the junction box and the solar panel is enlarged so that the clamping force therebetween is increased and the fixing strength therebetween can also be effectively increased. The junction box can be fixed to the solar panel with a fastener disposed at a contact area between the upper cover and the solar panel, and the lower cover and the solar panel to fix the junction box to the solar panel. In one embodiment, the fastener is the sealant applied to the contact area to glue the solar panel onto the solar panel. In another embodiment, the fastener is the fixing member, e.g. a bolt and a nut, can further be installed on the junction box to firmly clamp the solar panel with the two extending wings and the fixing member. In a further embodiment, the fastener is the protrusion respectively protruded from the upper cover and lower cover, and the solar panel further includes the trench defined therein to be engaged with the protrusion. In a still further embodiment, the fastener can be a combination selected from the sealant, the fixing member and the protrusion.

As is understood by a person skilled in the art, the foregoing preferred embodiments of the present invention are illustrative of the present invention rather than limiting of the present invention. It is intended that various modifications and similar arrangements be included within the spirit and scope of the appended claims, the scope of which should be accorded the broadest interpretation so as to encompass all such modifications and similar structures.

What is claimed is:

1. A junction box, comprising:
an upper cover, the upper cover having an upper base portion and an upper extending wing; and
a lower cover, the lower cover having a lower base portion and a lower extending wing, wherein the upper cover and the lower cover form a U-shaped clamp to clamp a solar panel when the upper base portion is coupled to the lower base portion;
wherein a fastener disposed at a contact area between the upper cover and the solar panel, and the lower cover and the solar panel to fix the junction box to the solar panel.

2. The junction box of claim 1, wherein the upper cover further comprises an upper cavity and the lower cover further comprises a lower cavity to form a protective room to protect electronic connections for the solar panel.

3. The junction box of claim 2, further comprising a sealant filled into the protective room formed by the upper cavity and the lower cavity to effectively protect the electronic connections.

4. The junction box of claim 1, wherein the fastener is a sealant applied to the contact area to glue the junction box onto the solar panel.

5. The junction box of claim 4, wherein the sealant is epoxy.

6. The junction box of claim 1, wherein the fastener is a protrusion respectively protruded from the upper cover and lower cover, and the solar panel further comprises a trench defined therein to be engaged with the protrusion.

7. The junction box of claim 1, wherein the fastener is a fixing member to couple the upper extending wing, the solar panel and the lower extending wing together.

8. The junction box of claim 7, wherein the fixing member comprises a bolt and a nut.

9. A photovoltaic module, comprising:
a solar panel having two conductive wires extending from the solar panel;
two terminals respectively connecting to the conductive wires;
two cables respectively connecting to the terminals; and
a junction box mounting on an edge of the solar panel, where the junction box comprises:
an upper cover, the upper cover having an upper base portion and an upper extending wing;
a lower cover, the lower cover having a lower base portion and a lower extending wing, wherein the upper cover and the lower cover are formed a U-shaped clamp to clamp the solar panel when the upper base portion is coupled to the lower base portion; and
a fastener, disposed at a contact area between the upper cover and the solar panel, and the lower cover and the solar panel to fix the junction box to the solar panel.

10. The photovoltaic module of claim 9, wherein the upper cover further comprises an upper cavity and the lower cover further comprises a lower cavity to form a protective room to protect electronic connections for the solar panel.

11. The photovoltaic module of claim 10, further comprising a sealant filled into the protective room formed by the upper cavity and the lower cavity to effectively protect the electronic connections.

12. The photovoltaic module of claim 9, wherein the fastener is a sealant applied to the contact area to glue the junction box onto the solar panel.

13. The photovoltaic module of claim 12, wherein the sealant is epoxy.

14. The photovoltaic module of claim 9, wherein the solar panel further comprises a trench, and the upper cover further comprises a protrusion to couple to the trench.

15. The photovoltaic module of claim 9, wherein the solar panel further comprises a trench, and the lower cover further comprises a protrusion to couple to the trench.

16. The photovoltaic module of claim 9, wherein the solar panel further comprises two trenches, and the upper cover and the lower cover comprise two protrusions to respectively couple to the trenches.

17. The photovoltaic module of claim 9, further comprising a fixing member to couple the upper extending wing, the solar panel and the lower extending wing together.
